(19) United States
(12) Patent Application Publication
(10) Pub. No.: US 2026/0026363 A1
(43) Pub. Date: Jan. 22, 2026

(54) ENHANCED VIDEO BANDWIDTH DEVICE PACKAGES

(71) Applicant: MACOM Technology Solutions Holdings, Inc., Lowell, MA (US)

(72) Inventor: Kyoung Joon Cho, Cary, NC (US)

(21) Appl. No.: 18/774,149

(22) Filed: Jul. 16, 2024

(51) Int. Cl. H01L 23/495; H01L 23/00; H01L 23/04; H01L 25/16

(52) U.S. Cl. CPC H01L 23/49541; H01L 23/041; H01L 23/49524; H01L 25/16; H01L 24/48; H01L 2224/48137; H01L 2224/48245

(57) ABSTRACT

Semiconductor device packages including leads for enhanced video bandwidth and related operating criteria are described. An example package includes a flange having a top surface, a frame secured to the flange, and a pair of output leads. The frame forms an air cavity bounded in part by the top surface of the flange. The pair of output leads extend from outside the frame, through at least a portion of the frame, and to within the air cavity. The package also includes a decoupling lead positioned between the pair of output leads. The package also includes a second decoupling lead positioned between the pair of output leads in some examples. The decoupling lead or leads between the output leads facilitate the use of off-package decoupling capacitors to meet video bandwidth and other operating specifications. The package can also include one or more additional decoupling leads between input leads.

### BACKGROUND

Various types of packages are available for integrated semiconductor devices, including digital and analog integrated circuits, power transistor amplifiers, and related devices. The packages can both protect and secure the components and provide electrically conductive leads for electrical couplings to the integrated semiconductor devices. Example package types include surface mount, through-hole mount, flange mount, flat package, chip carrier, pin grid array, and chip-scale packages, and other packaging formats are known in the field. The type, size, lead style, structure, materials, and other characteristics of a package can be selected based on the type of components being housed within the package, as well as the application for the components. Certain packages can be more or less suitable for components used in high power and high frequency applications.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

Semiconductor device packages including decoupling leads for enhanced video bandwidth and related operating criteria are described. An example package includes a flange having a top surface, a frame secured to the flange, and a pair of output leads. The frame forms an air cavity bounded in part by the top surface of the flange. The pair of output leads extend from outside the frame, through at least a portion of the frame, and to within the air cavity. The package also includes a decoupling lead positioned between the pair of output leads. The package also includes a second decoupling lead positioned between the pair of output leads in some examples. The decoupling lead or leads between the output leads facilitate the use of off-package decoupling capacitors to meet video bandwidth and other operating specifications. The package can also include one or more additional decoupling leads between input leads.

In other aspects, each output lead among the pair of output leads is positioned along a first side of the frame, and the decoupling lead is positioned along the first side of the frame and between the pair of output leads. The package can also include a second decoupling lead positioned between the pair of output leads along the first side of the frame. The package can also include another decoupling lead positioned outside of the pair of output leads along an end side of the frame. In some cases, the package can additionally include two decoupling leads positioned outside of the pair of output leads along an end side of the frame.

In other aspects, the package can include a pair of input leads extending from outside the frame, through at least a portion of the frame, and to within the air cavity. The package can also include a second decoupling lead positioned between the pair of input leads. In that case, each output lead among the pair of output leads can be positioned along a first side of the frame, and each input lead among the pair of input leads can be positioned along a second side of the frame. The second side of the frame can extend substantially parallel to the first side of the frame. The semiconductor device package can also include a second decoupling lead positioned along the second side of the frame and between the pair of input leads. The semiconductor device package can also include two decoupling leads positioned along the second side of the frame and between the pair of input leads.

In other examples, the package can include a main amplifier on the flange and coupled to a first output lead among the pair of output leads and a peaking amplifier on the flange and coupled to a second output lead among the pair of output leads. The package can include an output matching network on the flange for the main amplifier, and the decoupling lead can be coupled to the output matching network for the main amplifier. The package can include an output matching network on the flange for the peaking amplifier, and the decoupling lead can be coupled to the output matching network for the peaking amplifier. The package can also include an output matching network on the flange for the peaking amplifier. A second decoupling lead can be positioned between the pair of output leads, and the second decoupling lead can be coupled to the output matching network for the peaking amplifier.

In still other examples, the package can include an output matching network on the flange, and the decoupling lead can be coupled to the output matching network. The package can include an output matching network on the flange, and a second decoupling lead can be positioned between the pair of output leads. In that case, the decoupling lead can be coupled to one side of the output matching network and the second decoupling lead can be coupled to another side of the output matching network.

Another example semiconductor device package includes a frame, a pair of output leads, and a decoupling lead positioned between the pair of output leads. Each output lead among the pair of output leads can be positioned along a first side of the frame, and the decoupling lead can be positioned along the first side of the frame and between the pair of output leads. The semiconductor device package can also include a second decoupling lead positioned between the pair of output leads along the first side of the frame. The package can also include a second decoupling lead positioned outside of the pair of output leads along an end side of the frame. The semiconductor package can also include a pair of input leads and a second decoupling lead positioned between the pair of input leads.

Another example semiconductor device package includes a flange with a top surface, a frame secured to the flange, an output lead, and a decoupling lead. The frame forms an air cavity bounded in part by the top surface of the flange. The output lead extends from outside the frame, through at least a portion of the frame, and to within the air cavity. The output lead includes an output lead bonding strip positioned over the frame. The decoupling lead includes a decoupling lead bonding strip positioned over the frame. The output lead bonding strip extends parallel to the decoupling lead bonding strip over a region of the frame. In the region of the frame, the output lead bonding strip is positioned between a side of the frame and the decoupling lead bonding strip.

The frame can also include a second decoupling lead. The second decoupling lead can extend from outside the frame, through at least a portion of the frame, and to within the air cavity. The second decoupling lead includes a second decoupling lead bonding strip positioned over the frame. Along one side of the frame, the output lead is positioned between the decoupling lead and the second decoupling lead. The output lead bonding strip extends parallel to the second decoupling lead bonding strip over a second region of the frame. The output lead bonding strip, the decoupling lead bonding strip, and the second decoupling lead bonding strip all extend parallel to each other in some examples.

Another semiconductor device package includes a flange with a top surface, a frame secured to the flange, a lead extending from outside the frame and through at least a portion of the frame, and a decoupling lead extending from outside the frame and through at least a portion of the frame. The lead includes a lead bonding strip positioned over the frame. The decoupling lead includes a decoupling lead bonding strip positioned over the frame. The lead bonding strip extends parallel to the decoupling lead bonding strip over a region of the frame.

Another semiconductor device package includes a flange with a top surface, a frame secured to the flange, an output lead including an output lead bonding strip positioned over the frame, and a pair of decoupling leads including a pair of decoupling lead bonding strips positioned over the frame. Along one side of the frame, the output lead is positioned between the pair of decoupling leads, and the output lead bonding strip extends parallel to the decoupling lead bonding strips over a region of the frame. In a region of the frame, the output lead bonding strip is positioned between along the one side of the frame and the pair of decoupling lead bonding strips. In the region of the frame, the pair of decoupling lead bonding strips extend towards each other.

### BRIEF DESCRIPTION OF THE DRAWINGS

Aspects of the present disclosure can be better understood with reference to the following drawings. It is noted that the elements in the drawings are not necessarily to scale, with emphasis instead being placed upon clearly illustrating the principles of the embodiments. Among the figures of the drawings, like reference numerals designate similar or corresponding, but not necessarily the same, elements throughout the several views.

FIG. 1 illustrates a perspective view of a semiconductor device package according to various embodiments described herein.

FIG. 2 illustrates a top view of the semiconductor device package shown in FIG. 1 with the cover removed according to various embodiments described herein.

FIG. 3 illustrates another example semiconductor device package with the cover removed according to various embodiments described herein.

FIG. 4A illustrates another example semiconductor device package with the cover removed according to various embodiments described herein.

FIG. 4B illustrates a region of the semiconductor device package shown in FIG. 4A according to various embodiments described herein.

### DETAILED DESCRIPTION

A number of different packages are available for electrical components, including devices formed on semiconductor die. The packages can both protect and secure the components and provide electrically conductive leads for the components. As examples, flat no-leads packages such as quad-flat no-leads (QFN) packages can be used to physically secure and electrically connect semiconductor devices and integrated circuits to printed circuit boards (PCBs). Flat no-leads packages are one of several types of packages that can be used to connect devices to PCBs without through holes.

Packages including air cavities are also used for semiconductor devices, such as power transistors, for high power and high frequency applications, because dielectric capacitances can be minimized, among other benefits. Air cavity packages can include leads and be mounted on PCBs, in through holes of PCBs, and in other configurations. Some packages are more suitable for components used in high power and high frequency applications, and the type, size, lead style, structure, materials, and other characteristics of packages can be selected and designed based on the types of components being housed within them, as well as the application for the components.

Many radio frequency (RF) power amplifiers for wireless communications infrastructure use Class A, Class AB, or Doherty amplifiers. Doherty power amplifiers are often used to amplify RF signals having high peak-to-average power ratios (PAPRs) at relatively high power and efficiency. The linearity of power amplifiers can be particularly important for wideband amplification performance.

The specifications for power amplifiers used in fifth generation (5G) cellular network systems rely upon wider bandwidths, such as video bandwidth (VBW) of about 600 Mhz or greater. Third and even fifth order intermodulation distortion can be of concern for such wideband amplification applications. Intermodulation distortion also negatively impacts the linearity of power amplifiers, and the reduction of intermodulation distortion is one goal to improve linearity. Some Doherty amplifiers incorporate predistortion linearization technologies, such as digital predistortion (DPD), to improve linearization and spectral requirements.

The reduction of memory effects is also important in power amplifiers and can improve linearity. Memory effects are attributed in part to baseband impedance, and baseband impedance is mainly determined by the impedance of the matching and biasing networks of power amplifiers. Multiple capacitors can be used in the matching networks of Doherty amplifiers to improve baseband impedance, impedance matching, reduce memory effects, and improve VBW.

Overall, the input matching, output matching, and biasing networks for power amplifiers can significantly impact the VBW, memory effect, and linearity of power amplifiers. Thus, the designs of the matching and biasing networks for power amplifiers, and for both the main and the peaking amplifiers in Doherty power amplifiers, can be important for wideband applications. Some packages are designed for and include features to tailor and improve the input matching, output matching, and biasing networks for the power amplifiers packaged within them.

In the context outlined above, the embodiments described herein are directed to semiconductor device packages including decoupling leads for enhanced video bandwidth and related operating criteria. An example package includes a flange having a top surface, a frame secured to the flange, and a pair of output leads. The frame forms an air cavity bounded in part by the top surface of the flange. The pair of output leads extend from outside the frame, through at least a portion of the frame, and to within the air cavity. The package also includes a decoupling lead positioned between the pair of output leads. The package also includes a second decoupling lead positioned between the pair of output leads in some examples. The decoupling lead or leads between the output leads facilitate the use of off-package decoupling capacitors to meet video bandwidth and other operating specifications. The package can also include one or more additional decoupling leads between input leads. These and other aspects of the embodiments are described below.

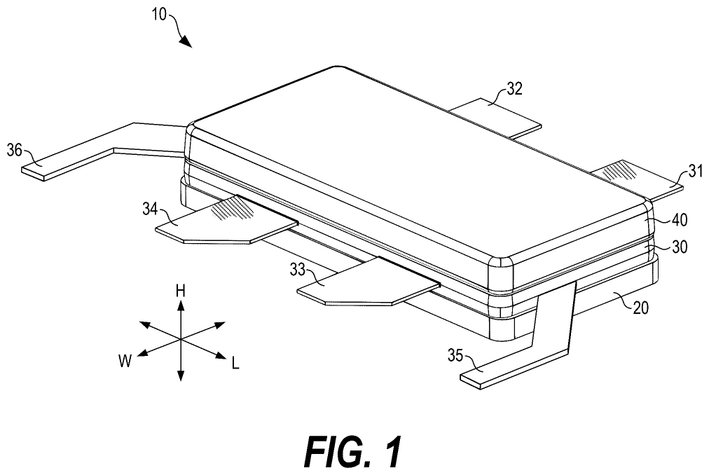

Turning to the drawings, FIG. 1 illustrates a perspective view of an example semiconductor device package 10 (also “package 10”). The package 10 is depicted as a representative example. The package 10 is not drawn to scale, and other packages consistent with the concepts described herein can vary in shape and/or size as compared to that shown. For example, the length “L,” width “W,” and height “H” of the package 10 can vary among the embodiments. The size, number, and positions of the conductive leads of the package 10 can vary in some cases. Overall, the incorporation of enhanced video bandwidth leads and device packages that support enhanced video bandwidth are not limited to any particular package type, size, lead style, or structure.

Referring to FIG. 1, the package 10 includes a flange 20, a frame 30 secured to a top surface of the flange 20, and a cover 40 secured over the frame 30. An air cavity is formed within the package 10. The air cavity is bounded by the top surface of the flange 20, the frame 30, and the cover 40. A number of semiconductors devices on semiconductor die can be secured within the package 10, as described below. Because the devices and components within the air cavity are not surrounded by (i.e., in contact with) package molding materials, they are not subject to electrical effects due to the materials (e.g., parasitic capacitances, etc.). The concepts and embodiments described herein can be applied to other types of packages, however, including overmold packages without air cavities and other types of packages.

The package 10 also includes a number of conductive leads 31-36 (also “leads 31-36”), each of which extends from outside the frame 30, across or through at least a portion of the frame 30, and is exposed in part within the air cavity inside the package 10. The semiconductor devices in the package 10 can be electrically coupled, using wire bonds or other means, to the exposed portions of the conductive leads 31-36 within the package 10, as described in additional detail below. The conductive leads 31-36 can be formed from Tin (Sn), Copper (Cu), Aluminum (Al), Silver (Ag), Gold (Au), Zinc (Zn), other metals, and compositions thereof, and the conductive leads 31-36 can be plated with Ag, Au, Nickel (Ni), Palladium (Pd), or other metals using full plating, spot-plating or other techniques.

The flange 20 can be embodied as a conductive slug of metal, such as a slug formed from Cu, Al, Ag, Molybdenum (Mo), or other metals and can be plated in some cases. In some cases, the flange 20 can be embodied as a composite core of metal or metal alloy with other materials or particles, such as diamond particles, distributed in the metal or metal alloy. The flange 20 can serve as a conductive lead of the package 10 in some cases, as the flange 20 can be electrically conductive. Thus, a semiconductor device die including a metal layer on the bottom surface of the die can be electrically coupled to the top surface of the flange 20 within the package 10. The flange 20 can act as a type of lead for the package 10 in that case. In other cases, the flange 20 can act as a heat sink but not an electrical contact.

As described in further detail below, the frame 30 is formed to have a ring or frame shape, with a central opening. The frame 30 can be formed by molding plastic or polymers, such as liquid crystal polymers (LCPs) or polymer blends, with or without glass, carbon, or other reinforcements, among other materials. In other examples, the frame 30 can be formed using ceramic materials. In that case, the frame 30 can be formed from a ceramic material, and the cover 40 can be formed as a ceramic, metal, or glass lid. The frame 30 is not limited to being formed from any particular material(s), however. The frame 30 can be formed using a range of suitable materials selected to provide protection (e.g., protection against temperatures, vibration, moisture, and other conditions) for the components in the package 10, mechanical strength, matching of the thermal expansion as compared to other materials in the package 10, and other relevant factors.

The cover 40 can be formed from plastic or other materials similar to that of the frame 30. In other cases, the cover 40 can be formed using ceramic, glass, metal, or other materials. The cover 40 can be secured over the frame 30 using any suitable means or methods, including epoxy or other adhesives, plastic welding, melting, and other approaches. The cover 40 can be secured over the frame 30 to create a hermetic (or near hermetic) seal for the package 10 in some cases.

The frame 30 includes an open central region, which encircles the air cavity formed between a top surface of the flange 20, the inner periphery of the frame 30, and the underside of the cover 40 in the package 10. The flange 20 and the frame 30 are secured together to create a seal between them. The bottom surface of the frame 30 can be secured to the top surface of the flange 20 using an adhesive, such as epoxy or another plastic adhesive, using mechanical interlocks or interferences, using fasteners, or combinations thereof. In other cases, the bottom surface of the frame 30 can be secured to the top surface 21 of the flange 20 by welding, heating, brazing or soldering.

After the frame 30 is secured to the flange 20, the cover 40 can be secured to the frame 30. The bottom surface of the cover 40 can be secured to the top of the frame 30 using adhesives, such as epoxy or other plastic adhesives, plastic welding, heating, or melting processes, using mechanical interlocks or interferences, using fasteners, or combinations thereof. The materials used for the cover 40 can also be selected provide protection against vibrations, moisture, and other conditions for the components in the package 10, mechanical strength, adequate matching of the thermal expansion as compared to other materials in the package 10, and other relevant factors. In some cases, the cover 40 can be hermetically sealed to the frame 30, and the package 10 can be a hermetically sealed package.

The package 10 is suitable for packaging RF power amplifiers for wireless communications applications, such as Doherty amplifiers, as one example. Doherty amplifiers include a main amplifier and a peaking amplifier, which can be implemented on two separate semiconductor die in some cases. The main and peaking amplifiers can be embodied as power transistors formed in Gallium Nitride (GaN) material(s), as one example, but the amplifiers within the package 10 are not limited to any particular type or technology of semiconductor materials. The main and peaking amplifiers operate in parallel on an input RF signal, which is divided into parallel circuit branches by a power coupler. The peaking amplifier is typically idle (e.g., not amplifying) at relatively low input RF signal levels, and the peaking amplifier turns on when the main amplifier begins to saturate. Outputs from the main and peaking amplifiers and are subsequently combined into a single RF output.

When the package 10 includes power amplifiers for a Doherty amplifier, the leads 31 and 32 can be electrically coupled to the gate terminals of the main and peaking power amplifiers, respectively, as amplifier input leads or terminals. Thus, the leads 31 and 32 can be referred to as input leads. The leads 33 and 34 can be electrically coupled to the drain terminals of the main and peaking power amplifiers, respectively, as amplifier output leads or terminals. Thus, the leads 33 and 34 can be referred to as output leads. The source terminals of the main and peaking power amplifiers can be electrically coupled to the flange 20.

Along with the main and peaking power amplifiers, the package 10 can also include one or more input matching networks, output matching networks, biasing networks, and combinations of such networks (collectively “matching networks”) for the main and peaking power amplifiers. The input matching, output matching, and biasing networks can be embodied as networks of reactive components (e.g., “L,” “C,” and “LC” networks), including combinations of one or more capacitors and inductors.

The reduction of memory effects and related phenomenon is important in packaged power amplifiers to improve linearity and related specifications. In some cases, a relatively significant capacitance is needed in the matching networks of Doherty amplifiers to improve impedance matching, reduce memory effects, and improve VBW. A large number of capacitors may be needed to establish the capacitance needed for certain VBW specifications, particularly if the capacitors are on-semiconductor-die capacitors having capacitances in the nanofarad (i.e., nF) range. Capacitances in the microfarad (i.e., μF) range may be needed in some cases to meet certain VBW and other operating specifications. It can be difficult or prohibitive to implement microfarad capacitances using on-semiconductor-die capacitors.

In the package 10, the conductive leads 35 and 36 are electrically coupled to the output matching networks of the main and peaking amplifiers. The conductive leads 35 and 36 facilitate the use of off-package decoupling capacitors to meet VBW and other operating specifications. That is, any capacitors coupled between the conductive leads 35 and 36 and ground can be helpful to meet VBW and other operating specifications. The conductive leads 35 and 36 can be referred to as decoupling leads or terminals for that reason. The conductive leads 35 and 36 can also be referred to as video bandwidth enhancement leads, as any capacitors coupled between the conductive leads 35 and 36 and ground can be helpful to meet VBW and other operating specifications. One or more ceramic capacitors, for example, having capacitances in the microfarad range can be electrically coupled between the conductive leads 35 and 36 and ground to improve the VBW specifications for the amplifiers in the package 10.

The conductive leads 35 and 36 can be insufficient in some cases, however. For example, off-package capacitors may also be needed for the input matching networks of the main and peaking amplifiers. Additionally, some impedance matching networks rely upon dual- or multi-branch matching networks, with inductors separating each branch and decoupling capacitors at the end of each branch. A capacitance in the microfarad range may be needed for each branch in some cases, but the conductive leads 35 and 36 can only support an off-package capacitor for a single branch.

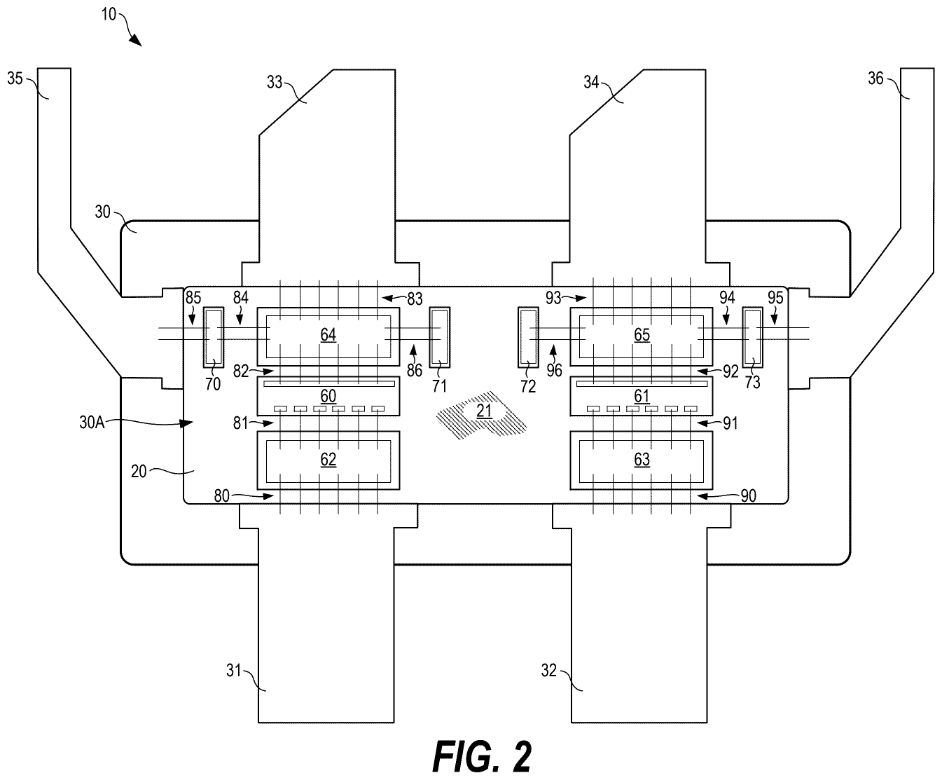

FIG. 2 illustrates a top view of the semiconductor device package 10 shown in FIG. 1 with the cover 40 removed. The frame 30 includes an open central region 30A which forms part of an air cavity between a top surface 21 of the flange 20, the frame 30, and the underside of the cover 40 in the package 10 (not shown in FIG. 2). A number of semiconductor die, including power transistor amplifiers, matching networks, and other circuit elements are attached and secured to the top surface 21 of the flange 20 in the example shown. The active devices, passive devices, and other components on the semiconductor die are electrically coupled among each other and to the conductive leads 31-36 by bond wires, as described in further detail below. The arrangement of semiconductor die and bond wires is depicted as a representative example in FIG. 2. Other arrangements are within the scope of the embodiments. Additional components can also be added, and one or more of the semiconductor die can also be omitted in some cases.

FIG. 2 illustrates semiconductor die for a first or main power amplifier transistor 60 (also “amplifier 60”), a second or peaking power amplifier transistor 61 (also “amplifier 61”), a first input matching network 62, a second input matching network 63, a first output matching network 64, and a second output matching network 65. FIG. 2 also illustrates semiconductor die for termination capacitors 70-73. The amplifiers 60 and 61 can each be embodied as a power transistor formed in GaN materials on a semiconductor die or suitable substrate. Each of the matching networks 62-65 can be embodied as a network of reactive components, such as an arrangement of inductors and capacitors, implemented on a semiconductor die or suitable substrate. The matching networks 62-65 can also include resistors, transmission lines, and related components for matching networks in some cases. The termination capacitors 70-73 can be embodied as capacitors implemented on a semiconductor die or suitable substrate. The termination capacitors 70-73 are electrically coupled to and may be considered components of the output matching networks 64 and 65 in the example shown. More particularly, the termination capacitors 70 and 71 are positioned at opposite ends of and are electrically coupled to the output matching network 64, and the termination capacitors 72 and 73 are positioned at opposite ends of and are electrically coupled to the output matching network 65.

The matching networks 62-65 and termination capacitors 70-73 can be relied upon for harmonic termination, input impedance matching, output impedance matching, memory effect control, VBW control, and to tailor other operating aspects of the amplifiers 60 and 61. Depending on the needs for impedance matching, memory effect control, VBW control, etc., one or more of the input matching networks 62 and 63, output matching networks 64 and 65, and termination capacitors 70-73 can be omitted in some cases.

As shown in FIG. 2, the amplifiers 60 and 61, matching networks 62-65, and termination capacitors 70-73 can be mounted to the top surface 21 of the flange 20 (see also FIG. 1 for the flange 20). The bottom surfaces of certain semiconductor die can be electrically coupled to the top surface 21 of flange 20 itself. For example, the bottom surfaces of the semiconductor die on which the amplifiers 60 and 61 are implemented can be electrically coupled to the top surface 21 of the flange 20. The flange 20 can act as a source contact or lead for both the amplifiers 60 and amplifier 61 in that case. The matching networks 62-65 and termination capacitors 70-73 can also be electrically coupled to the flange 20 in a similar way. Each semiconductor die can be secured to the top surface 21 of the flange 20 using thermal epoxy, solder, solder preforms, sintered die attach, or other suitable means.

The amplifiers 60 and 61, matching networks 62-65, and termination capacitors 70-73 are also electrically coupled to the conductive leads 31-36 of the package 10 and each other using wire bonds in the example shown. The wire bonds 80 are electrically coupled between the conductive lead 31 and the first input matching network 62. The wire bonds 81 are electrically coupled between the first input matching network 62 and the main amplifier 60. The wire bonds 82 are electrically coupled between the main amplifier 60 and the first output matching network 64. The wire bonds 83 are electrically coupled between the first output matching network 64 and the conductive lead 33. The wire bonds 84 are electrically coupled between the first output matching network 64 and the termination capacitor 70. The wire bonds 85 are electrically coupled between the termination capacitor 70 and the conductive lead 35. The wire bonds 86 are electrically coupled between the first output matching network 64 and the termination capacitor 71. Any suitable type and number of wire bonds can be used, such as gold bond wires of suitable diameter or thickness, for the wire bonds 80-86.

Additionally, the wire bonds 90 are electrically coupled between the conductive lead 32 and the second input matching network 63. The wire bonds 91 are electrically coupled between the second input matching network 63 and the peaking amplifier 61. The wire bonds 92 are electrically coupled between the peaking amplifier 61 and the second output matching network 65. The wire bonds 93 are electrically coupled between the second output matching network 65 and the conductive lead 34. The wire bonds 94 are electrically coupled between the second output matching network 65 and the termination capacitor 73. The wire bonds 95 are electrically coupled between the termination capacitor 73 and the conductive lead 35. The wire bonds 96 are electrically coupled between the second output matching network 65 and the termination capacitor 72. Any suitable type and number of wire bonds can be used, such as gold bond wires of suitable diameter or thickness, for the wire bonds 90-96.

The amplifier 60, first input matching network 62, and first output matching network 64 in the package 10 can operate collectively as a single three-terminal active device. Particularly, the amplifier 60 can operate as a single common source transistor amplifier, with the conductive lead 31 acting as a gate input, the conductive lead 33 acting as a drain output, and the flange 20 acting as a common source. The amplifier 61, second input matching network 63, and second output matching network 65 in the package 10 can operate collectively as another single three-terminal active device. Particularly, the amplifier 61 can operate as a single common source transistor amplifier, with the conductive lead 32 acting as a gate input, the conductive lead 34 acting as a drain output, and the flange 20 acting as a common source.

The termination capacitors 70-73 are electrically coupled to and may be considered components of the output matching networks 64 and 65 in the example shown. The termination capacitors 70-73 can operate as decoupling capacitors for the output matching networks 64 and 65. Being implemented as on-semiconductor-die capacitors, each of the termination capacitors 70-73 may exhibit capacitances in the nF range. Capacitances in the μF range, however, may be needed to meet VBW and other operating specifications for the amplifiers in the package 10 in some cases. It can be difficult to implement microfarad capacitances using the termination capacitors 70-73, as increasing the capacitances of the termination capacitors 70-73 can only be achieved by using prohibitively large die sizes. Additionally, the termination capacitors 70-73 may have relatively lower breakdown voltages as compared to other types of capacitors.

As a solution for increased decoupling capacitances, the conductive lead 35 is electrically coupled to the output matching network 64 of the amplifier 60. Similarly, the conductive lead 36 is electrically coupled to the output matching network 65 of the amplifier 61. Thus, the conductive leads 35 and 36 facilitate the use of off-package decoupling capacitors. External capacitors (i.e., capacitors outside of the package 10) coupled between the conductive leads 35 and 36 and ground also act as decoupling capacitors, as they are electrically coupled in parallel with the termination capacitors 70 and 73, respectively, and can be helpful to meet VBW and other operating specifications. The conductive leads 35 and 36 can be referred to as decoupling leads or terminals for that reason. One or more ceramic capacitors, for example, having capacitances in the microfarad range can be electrically coupled between the conductive leads 35 and 36 and ground to improve the VBW specifications for the amplifiers in the package 10. Ceramic capacitors also have relatively higher breakdown voltages as compared to the termination capacitors 70-73.

Decoupling through the conductive leads 35 and 36 can still be insufficient in some cases, however. For example, off-package capacitors may also be needed for the first input matching network 62 and the second input matching network 63. As another example, some impedance matching networks can rely upon dual- or multi-branch matching networks, with inductors separating each branch and decoupling capacitors at the end of each branch. The first output matching network 64, for example, can rely upon the termination capacitor 70 as a decoupling capacitor for the first branch. The first output matching network 64 can also rely upon the termination capacitor 71 as a decoupling capacitor for the second branch. However, the package 10 does not include a separate conductive lead for an off-package decoupling capacitor arranged in parallel with the termination capacitor 71.

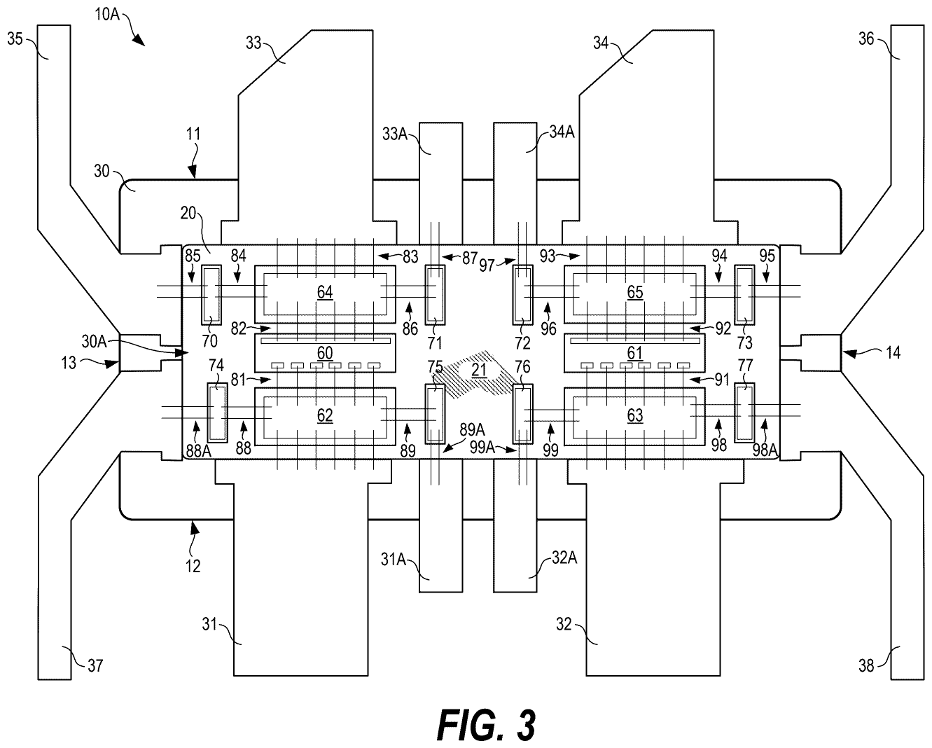

FIG. 3 illustrates another example semiconductor device package 10A (also “package 10A”) according to various embodiments described herein. The package 10A includes a flange 20, a frame 30 secured to a top surface 21 of the flange 20, and a cover 40 secured over the frame 30. The cover 40 is omitted from view in FIG. 3. The package 10A is depicted as a representative example. The package 10A is not drawn to scale, and other packages consistent with the concepts described herein can vary in shape and/or size as compared to that shown. The size, number, and respective positions of the conductive leads of the package 10A can vary in some cases. The arrangement of semiconductor die and bond wires in the package 10A is also depicted as a representative example in FIG. 3. Other arrangements are within the scope of the embodiments. Additional components can also be added, and one or more of the semiconductor die can also be omitted in some cases.

The package 10A is similar to the package 10 shown in FIGS. 1 and 2 and includes a flange 20 and a frame 30. As compared to the package 10, the package 10A also includes conductive leads 31A, 32A, 37, 38, 33A, and 34A and termination capacitors 74-77. Capacitors coupled between the conductive leads 31A, 32A, 37, 38, 33A, and 34A and ground can act as decoupling capacitors, and the conductive leads 31A, 32A, 37, 38, 33A, and 34A can be referred to as decoupling leads or terminals for that reason.

FIG. 3 illustrates the amplifiers 60 and 61, first input matching network 62, second input matching network 63, first output matching network 64, second output matching network 65, and termination capacitors 70-73. FIG. 3 also illustrates the termination capacitors 74-77. The termination capacitors 74-77 can be embodied as capacitors implemented on a semiconductor die or suitable substrate. The termination capacitors 74-77 are electrically coupled to and may be considered components of the output matching networks 62 and 63 in the example shown. More particularly, the termination capacitors 74 and 75 are positioned at opposite ends of and are electrically coupled to the output matching network 62, and the termination capacitors 76 and 77 are positioned at opposite ends of and are electrically coupled to the output matching network 63.

The amplifiers 60 and 61, matching networks 62-65, and termination capacitors 70-77 are electrically coupled to the conductive leads 31-38, 31A, 32A, 33A, and 34A of the package 10A and each other using wire bonds in the example shown. In addition to the electrical couplings shown in FIG. 2, FIG. 3 also illustrates wire bonds 87 electrically coupled between the termination capacitor 71 and the conductive lead 33A. The wire bonds 97 are electrically coupled between the termination capacitor 72 and the conductive lead 34A. The wire bonds 88 are electrically coupled between the input matching network 62 and the termination capacitor 74, and the wire bonds 88A are electrically coupled between the termination capacitor 74 and the conductive lead 37. The wire bonds 89 are electrically coupled between the input matching network 62 and the termination capacitor 75, and the wire bonds 89A are electrically coupled between the termination capacitor 75 and the conductive lead 31A. The wire bonds 98 are electrically coupled between the input matching network 63 and the termination capacitor 77, and the wire bonds 98A are electrically coupled between the termination capacitor 77 and the conductive lead 38. The wire bonds 99 are electrically coupled between the input matching network 63 and the termination capacitor 76, and the wire bonds 99A are electrically coupled between the termination capacitor 76 and the conductive lead 32A.

The termination capacitors 70-73 are electrically coupled to and may be considered components of the output matching networks 64 and 65 in the example shown. The termination capacitors 70-73 can operate as decoupling capacitors for the output matching networks 64 and 65. Additionally, the termination capacitors 74-77 are electrically coupled to and may be considered components of the input matching networks 62 and 63 in the example shown. The termination capacitors 74-77 can operate as decoupling capacitors for the input matching networks 62 and 63. Being implemented as on-semiconductor-die capacitors, each of the termination capacitors 70-77 may exhibit capacitances in the nF range. Capacitances in the μF range, however, may be needed to meet VBW and other operating specifications for the amplifiers in the package 10A in some cases.

The conductive lead 37 is electrically coupled to the termination capacitor 74 of the input matching network 62. Similarly, the conductive lead 38 is electrically coupled to termination capacitor 77 of the input matching network 63. The conductive leads 37 and 38 facilitate the use of off-package decoupling capacitors. External capacitors coupled between the conductive leads 37 and 38 and ground also act as decoupling capacitors, as they are electrically coupled in parallel with the termination capacitors 74 and 77, respectively, and can be helpful to meet VBW and other operating specifications. The conductive leads 37 and 38 can be referred to as decoupling leads or terminals for that reason. One or more ceramic capacitors, for example, having capacitances in the microfarad range can be electrically coupled between the conductive leads 37 and 38 and ground to improve the VBW specifications for the amplifiers in the package 10A. Ceramic capacitors also have relatively higher breakdown voltages as compared to the termination capacitors 74 and 77.

The package 10A also includes additional conductive leads for decoupling. The conductive lead 33A, for example, is positioned between the pair of output conductive leads 33 and 34. The conductive lead 34A is also positioned between the pair of output conductive leads 33 and 34. The conductive lead 33A is electrically coupled to the termination capacitor 71 of the output matching network 64. Similarly, the conductive lead 34A is electrically coupled to termination capacitor 72 of the output matching network 65. The conductive leads 33A and 34A facilitate the use of off-package decoupling capacitors. External capacitors coupled between the conductive leads 33A and 34A and ground also act as decoupling capacitors, as they are electrically coupled in parallel with the termination capacitors 71 and 72, respectively, and can be helpful to meet VBW and other operating specifications. The conductive leads 33A and 34A can be referred to as decoupling leads or terminals for that reason. One or more external ceramic capacitors, for example, having capacitances in the microfarad range can be electrically coupled between the conductive leads 33A and 34A and ground to improve the VBW specifications for the amplifiers in the package 10A.

Further, the conductive lead 31A is positioned between the pair of input conductive leads 31 and 32. The conductive lead 32A is also positioned between the pair of input conductive leads 31 and 32. The conductive lead 31A is electrically coupled to the termination capacitor 75 of the input matching network 62. Similarly, the conductive lead 32A is electrically coupled to termination capacitor 76 of the input matching network 63. The conductive leads 31A and 32A facilitate the use of off-package decoupling capacitors. External capacitors coupled between the conductive leads 31A and 32A and ground also act as decoupling capacitors, as they are electrically coupled in parallel with the termination capacitors 75 and 76, respectively, and can be helpful to meet VBW and other operating specifications. The conductive leads 31A and 32A can be referred to as decoupling leads or terminals for that reason. One or more ceramic capacitors, for example, having capacitances in the microfarad range can be electrically coupled between the conductive leads 31A and 32A and ground to improve the VBW specifications for the amplifiers in the package 10A.

The output conductive leads 33 and 34 and the decoupling conductive leads 33A and 34A are all positioned along the same side 11 of the package 10A, with the decoupling conductive leads 33A and 34A being positioned between the output conductive leads 33 and 34. The input conductive leads 31 and 32 and the decoupling conductive leads 31A and 32A are all positioned along the same side 12 of the package 10A, with the decoupling conductive leads 31A and 32A being positioned between the input conductive leads 31 and 32. The side 12 of the package 10A extends substantially parallel to the side 11.

The decoupling conductive leads 35 and 37 are both positioned along the side 13 of the package 10A. The decoupling conductive leads 36 and 38 are both positioned along the side 14 of the package 10A. The sides 13 and 14 of the package 10A extend substantially parallel to each other. The sides 13 and 14 extend substantially orthogonal to the sides 11 and 12, because the frame 30 of the package 10A is shaped as a parallelogram and more particularly as a rectangle. As noted above, however, the size and shape of the package 10A can vary among the embodiments.

The package 10A includes two conductive leads for decoupling for each of the matching networks 62-65. For example, the conductive lead 35 is positioned on and coupled to one side of the output matching network 64, and the conductive lead 33A is positioned on and coupled to another side of the output matching network 64. The two conductive leads 33A and 35 in the package 10A can increase the amount of off-package decoupling capacitance that can be electrically coupled to the output matching network 64 as compared to the package 10. As another example, the conductive lead 37 is positioned on and coupled to one side of the input matching network 62, and the conductive lead 31A is positioned on and coupled to another side of the input matching network 62. The two conductive leads 31A and 37 in the package 10A can increase the amount of off-package decoupling capacitance that can be electrically coupled to the input matching network 62 as compared to the package 10.

Variations on the package 10A and the semiconductor die secured within the package 10A are within the scope of the embodiments. As examples, other semiconductor packages can omit one or more of the conductive leads 31A, 32A, 35-38, 33A, 34A, omit one or more of the termination capacitors 70-77, or omit one or more of the conductive leads 31A, 32A, 35-38, 33A, 34A and omit one or more of the termination capacitors 70-77. In the example shown in FIG. 3, the conductive leads 31A, 32A, 35-38, 33A, 34A are electrically coupled, respectively, to the termination capacitors 75, 76, 70, 73, 74, 77, 71, and 72. Any one or more of the termination capacitors 75, 76, 70, 73, 74, 77, 71, and 72 can be omitted in some cases, and the corresponding or respective conductive lead can be directly coupled to the corresponding matching network 62-65. The embodiments also encompass the package 10A without any of the semiconductor die or wire bonds (i.e., just the package 10A itself).

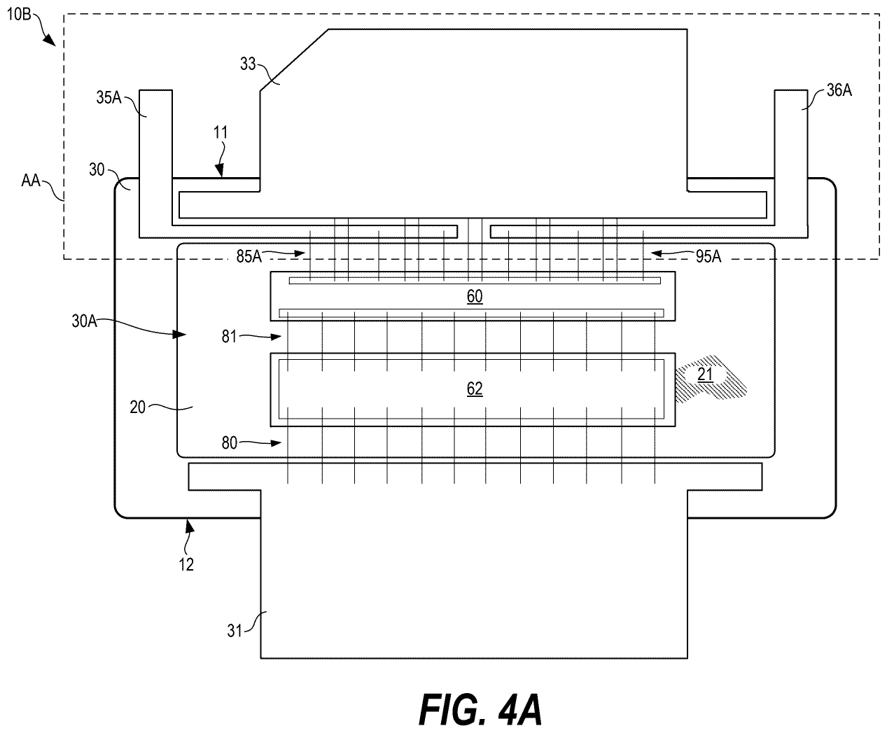

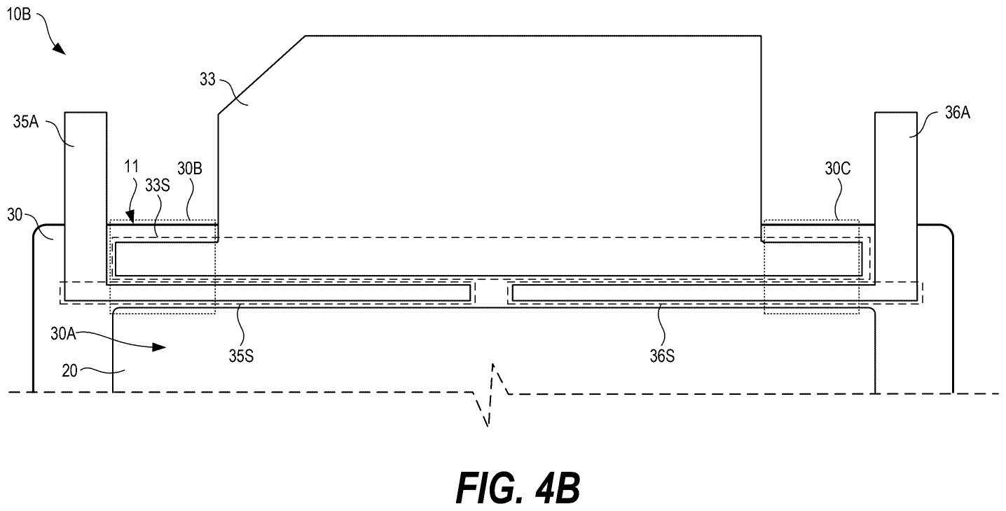

FIG. 4A illustrates another example semiconductor device package 10B (also “package 10B”) according to various embodiments described herein. The package 10B is depicted as a representative example. The package 10B is similar to the packages 10 and 10A shown in FIGS. 1-3 in some aspects. However, the package 10B is also different than the packages 10 and 10A in other aspects. The package 10B is not drawn to scale, and other packages consistent with the concepts described herein can vary in shape and/or size as compared to that shown. The size, number, and respective positions of the conductive leads of the package 10B can vary in some cases.

The package 10B includes a flange 20, a frame 30 secured to a top surface 21 of the flange 20, and a cover 40 secured over the frame 30. The cover 40 is omitted from view in FIG. 4A. The frame 30 includes an open central region 30A which forms part of an air cavity between a top surface 21 of the flange 20, the frame 30, and the underside of the cover 40. The frame 30 of the package 10B also includes conductive leads 31, 33, 35A, and 36A.

A number of semiconductor die, including the power transistor amplifier 60 and the input matching network 62, are attached and secured to the top surface 21 of the flange 20 in the example shown. The power transistor amplifier 60 and matching network 62 are electrically coupled among each other and to the conductive leads 31, 33, 35A, and 36A by bond wires, as described in further detail below. The arrangement of semiconductor die and bond wires is depicted as a representative example in FIG. 4A. Other arrangements are within the scope of the embodiments. Additional components can also be added, and one or more of the semiconductor die can also be omitted in some cases.

The lead 31 is electrically coupled to the gate terminal of the power transistor amplifier 60 as an amplifier input lead or terminal. Thus, the lead 31 can be referred to as an input lead. The lead 33 is electrically coupled to the drain terminal of the power transistor amplifier 60 as an amplifier output lead or terminal. Thus, the lead 33 can be referred to as an output lead. External capacitors coupled between the conductive leads 35A and 36A and ground can act as decoupling capacitors, and the conductive leads 35A and 36A can be referred to as decoupling leads or terminals.

The amplifier 60 and input matching network 62 are electrically coupled to the conductive leads 31, 33, 35A, and 36A of the package 10B and each other using wire bonds in the example shown. The wire bonds 80 are electrically coupled between the conductive lead 31 and the input matching network 62. The wire bonds 81 are electrically coupled between the input matching network 62 and the amplifier 60. The wire bonds 83A are electrically coupled between the amplifier 60 and the conductive lead 33. The wire bonds 85A are electrically coupled between the amplifier 60 and the conductive lead 35A, and the wire bonds 95A are electrically coupled between the amplifier 60 and the conductive lead 36A.

The amplifier 60 and first input matching network 62 in the package 10B can operate as a single three-terminal active device. Particularly, the amplifier 60 can operate as a single common source transistor amplifier, with the conductive lead 31 acting as a gate input, the conductive lead 33 acting as a drain output, and the flange 20 acting as a common source.

The conductive leads 35A and 36A facilitate the use of off-package decoupling capacitors. Capacitors coupled between the conductive leads 35A and 36A and ground can act as decoupling capacitors and can be helpful to meet VBW and other operating specifications. The conductive leads 35A and 36A can be referred to as decoupling leads or terminals for that reason. One or more external ceramic capacitors, for example, having capacitances in the microfarad range can be electrically coupled between the conductive leads 35A and 36A and ground to improve the VBW specifications for amplifiers in the package 10B.

The output conductive lead 33 is positioned between the decoupling conductive leads 35A and 36A. The output conductive lead 33 and the decoupling conductive leads 35A and 36A are all positioned along the same side 11 of the package 10B, with the conductive lead 33 being positioned between the decoupling conductive leads 35A and 36A. The input conductive lead 31 is positioned along the side 12 of the package 10B. The side 12 of the package 10B extends substantially parallel to the side 11.

The conductive lead 35A is coupled to one side of the amplifier 60, and the conductive lead 35B is coupled to another side of the amplifier 60. The conductive leads 35A and 36A facilitate the use of off-package decoupling capacitors with the package 10B, among other benefits. Without the conductive leads 35A and 36A, it may be necessary to rely upon a separate bridge capacitor, on a separate and additional semiconductor die, on the top surface 21 of the flange 20.

FIG. 4B illustrates the region “BB” of the package 10B shown in FIG. 4A. The amplifier 60, input matching network 62, and bond wires 80, 81, 85A, and 95A are omitted from view in FIG. 4B for simplicity. As shown in FIG. 4B, the output lead 33 includes an output lead bonding strip 33S. The decoupling lead 35A includes a decoupling lead bonding strip 35S, and the decoupling lead 36A includes a decoupling lead bonding strip 36S. Each of the decoupling leads 35A and 36A is formed in the shape an “L” in the example shown. The output lead bonding strip 33S, the decoupling lead bonding strip 35S, and the decoupling lead bonding strip 36S are all positioned over the frame 30 and can be embedded in part within the frame 30. Each of the bonding strips 33S, 35S, and 36S is also positioned over the frame 30 along the same side 11 of the frame 30.

The bonding strips 33S, 35S, and 36S run parallel to each other along the side 11 of the frame 30. For example, the output lead bonding strip 33S extends parallel to the decoupling lead bonding strip 35S over a region 30B of the frame 30. In the region 30B of the frame 30, the output lead bonding strip 33S is positioned between the side 11 of the frame 30 and the decoupling lead bonding strip 35S. Further, the output lead bonding strip 33S extends parallel to the decoupling lead bonding strip 36S over a region 30C of the frame 30. In the region 30C of the frame 30, the output lead bonding strip 33S is positioned between the side 11 of the frame 30 and the decoupling lead bonding strip 36S. The decoupling lead bonding strips 35S and 36S extend towards each other along the side 11 of the frame 30, but the decoupling lead bonding strips 35S and 36S do not contact each other and are electrically isolated from each other in the frame 30.

Referring between FIGS. 4A and 4B, the amplifier 60 is electrically coupled to the bonding strips of the conductive leads 33, 35A, and 36A using wire bonds. The wire bonds 83A are electrically coupled between the amplifier 60 and the output conductive lead 33, as shown in FIG. 4A, and more particularly between the amplifier 60 and the output lead bonding strip 33S (see FIG. 4B). The wire bonds 85A are electrically coupled between the amplifier 60 and the conductive lead 35A, and more particularly between the amplifier 60 and the decoupling lead bonding strip 35S (see FIG. 4B). The wire bonds 95A are electrically coupled between the amplifier 60 and the conductive lead 35A, and more particularly between the amplifier 60 and the decoupling lead bonding strip 35S (see FIG. 4B). The wire bonds 83A extend over the decoupling lead bonding strips 35S and 36S between the amplifier 60 and the output lead bonding strip 33S.

Variations on the package 10B and the semiconductor die secured within the package 10B are within the scope of the embodiments. As examples, the package 10B can omit one or more of the conductive leads 31, 33, 35A, and 36A in some cases. The package 10B can also include additional decoupling conductive leads similar to the decoupling conductive leads 35A and 36A but positioned along the side 12 of the package 10B. For example, the package 10B can include decoupling conductive leads positioned around the input lead 31 along the side 12 of the package 10B. The embodiments also encompass the package 10B without any of the semiconductor die or wire bonds (i.e., just the package 10B itself). Additionally, the embodiments described herein also encompass the frame 30 itself as illustrated in FIGS. 3, 4A, and 4B and described herein

Power transistors formed on semiconductor die can be packaged using the embodiments described herein. Among other types, the transistors described herein can be formed as high electron mobility transistors (HEMTs), pseudomorphic high-electron mobility transistors (pHEMTs), metamorphic high-electron mobility transistors (mHEMTs), laterally diffused metal oxide semiconductor transistors (LDMOS), metal-insulator-semiconductor field effect transistors (MISFETs or MISHFETs), metal-oxide-semiconductor field effect transistors (MOSFETs).

The power transistors described herein can be formed using a number of different semiconductor materials and semiconductor manufacturing processes. Example semiconductor materials include the group IV elemental semiconductor materials, including Silicon (Si) and Germanium (Ge), compounds thereof, and the group III elemental semiconductor materials, including Al, Gallium (Ga), Indium (In), and compounds thereof. Semiconductor transistor amplifiers can be constructed from group III-V direct bandgap semiconductor technologies, in certain cases, as the higher bandgaps and electron mobility provided by those devices can lead to higher electron velocity and breakdown voltages, among other benefits. Thus, in some examples, the concepts can be applied to group III-V direct bandgap active semiconductor devices, such as III-Nitride material devices (Aluminum (Al)-, Gallium (Ga)-, Indium (In)-, and their alloys (AlGaIn) based Nitrides), GaAs, InP, InGaP, AlGaAs, etc. devices. However, the principles and concepts can also be applied to transistors and other active devices formed from other semiconductor materials.

As used herein, the term “III-Nitride material(s)” or “Gallium Nitride material(s)” refers to any Group III element-nitride compound. Non-limiting examples of III-nitride materials include Boron Nitride (BN), Aluminum Nitride (AlN), Gallium Nitride (GaN), Indium Nitride (InN), and Thallium Nitride (TIN), as well as any alloys including Group III elements and Group V elements, such as Aluminum Gallium Nitride (AlₓGa₍₁₋ₓ₎N), Indium Gallium Nitride (In_{y}Ga_{(1-y)}N), Aluminum Indium Gallium Nitride (AlₓIn_{y}Ga_{(1-x-y)}N), Gallium Arsenide Phosphide nitride (GaAsₐP_{b}N_{(1-a-b)}), Aluminum Indium Gallium Arsenide Phosphide Nitride (AlₓIn_{y}Ga_{(1-x-y)}AsₐP_{b}N_{(1-a-b)}), among others. Typically, when present, Arsenic and/or Phosphorous are at low concentrations (e.g., less than 5 weight percent). The term “Gallium Nitride” or GaN semiconductor refers directly to gallium nitride, exclusive of its alloys.

According to certain embodiments, the substrates of the semiconductor devices described herein can include Silicon (Si) (i.e., a substrate containing the Si in any form). Examples of substrates comprising Si that can be used in various embodiments include, but are not limited to, SiC substrates, bulk Si wafers, Si-on-insulator (SOI) substrates, Silicon-on-sapphire (SOS) substrates, and separation by implantation of oxygen (SIMOX) substrates, among others. Suitable Silicon substrates also include composite substrates that include a Si wafer bonded to another material such as diamond, AlN, SiC, or other polycrystalline materials. Silicon substrates having different crystallographic orientations can be used, though single crystal silicon substrates can be preferred in certain, but not necessarily all, embodiments. In some embodiments, Silicon (111) substrates are used. A III-Nitride or GaN transistor can be a III-Nitride heterostructure FET (III-N HFET), a metal-insulator-semiconductor FET (MISFET or MISHFET), such as a metal-oxide-semiconductor FET (MOSFET). Alternatively, when implemented as an HFET, III-Nitride transistor can be a HEMT configured to produce a 2DEG.

The features, structures, and characteristics described above may be combined in one or more embodiments in any suitable manner, and the features discussed in the various embodiments are interchangeable in many cases. Although relative terms such as “on,” “below,” “upper,” “lower,” “top,” “bottom,” “right,” and “left” may be used to describe the relative spatial relationships of certain structural features, these terms are used for convenience only, as a direction in the examples. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. are used only as labels, rather than a limitation for a number of the objects.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be interpreted to encompass modifications and equivalent structures.

1. A semiconductor device package, comprising:
a flange comprising a top surface;
a frame secured to the flange, the frame forming an air cavity bounded in part by the top surface of the flange;
a pair of output leads extending from outside the frame, through at least a portion of the frame, and to within the air cavity; and
a decoupling lead positioned between the pair of output leads.

2. The semiconductor device package according to claim 1, wherein:
each output lead among the pair of output leads is positioned along a first side of the frame; and
the decoupling lead is positioned along the first side of the frame and between the pair of output leads.

3. The semiconductor device package according to claim 2, further comprising a second decoupling lead positioned between the pair of output leads along the first side of the frame.

4. The semiconductor device package according to claim 2, further comprising a second decoupling lead positioned outside of the pair of output leads along an end side of the frame.

5. The semiconductor device package according to claim 4, further comprising a third decoupling lead positioned outside of the pair of output leads along the end side of the frame.

6. The semiconductor device package according to claim 1, further comprising:
a pair of input leads extending from outside the frame, through at least a portion of the frame, and to within the air cavity; and
a second decoupling lead positioned between the pair of input leads.

7. The semiconductor device package according to claim 1, wherein:
each output lead among the pair of output leads is positioned along a first side of the frame;
each input lead among the pair of input leads is positioned along a second side of the frame, the second side of the frame extending substantially parallel to the first side of the frame; and
the semiconductor device package further comprises a second decoupling lead positioned along the second side of the frame and between the pair of input leads.

8. The semiconductor device package according to claim 7, further comprising a third decoupling lead positioned between the pair of input leads along the second side of the frame.

9. The semiconductor device package according to claim 1, further comprising:
a main amplifier on the flange and coupled to a first output lead among the pair of output leads; and
a peaking amplifier on the flange and coupled to a second output lead among the pair of output leads.

10. The semiconductor device package according to claim 9, further comprising an output matching network on the flange for the main amplifier, wherein the decoupling lead is coupled to the output matching network for the main amplifier.

11. The semiconductor device package according to claim 9, further comprising an output matching network on the flange for the peaking amplifier, wherein the decoupling lead is coupled to the output matching network for the peaking amplifier.

12. The semiconductor device package according to claim 10, further comprising:
an output matching network on the flange for the peaking amplifier; and
a second decoupling lead positioned between the pair of output leads, wherein the second decoupling lead is coupled to the output matching network for the peaking amplifier.

13. The semiconductor device package according to claim 1, further comprising an output matching network on the flange, wherein the decoupling lead is coupled to the output matching network.

14. The semiconductor device package according to claim 1, further comprising:
an output matching network on the flange; and
a second decoupling lead positioned between the pair of output leads, wherein:
the decoupling lead is coupled to one side of the output matching network; and
the second decoupling lead is coupled to another side of the output matching network.

15. The semiconductor device package according to claim 1, further comprising:
an output matching network on the flange; and
a termination capacitor on the flange, wherein the decoupling lead is coupled to the termination capacitor.

16. A semiconductor device package, comprising:
a frame;
a pair of output leads; and
a decoupling lead positioned between the pair of output leads.

17. The semiconductor device package according to claim 16, wherein:
each output lead among the pair of output leads is positioned along a first side of the frame; and
the decoupling lead is positioned along the first side of the frame and between the pair of output leads.

18. The semiconductor device package according to claim 17, further comprising a second decoupling lead positioned between the pair of output leads along the first side of the frame.

19. The semiconductor device package according to claim 17, further comprising a second decoupling lead positioned outside of the pair of output leads along an end side of the frame.

20. The semiconductor device package according to claim 16, further comprising:
a pair of input leads; and
a second decoupling lead positioned between the pair of input leads.

21-40. (canceled)
